(19) United States
(12) Patent Application Publication
(10) Pub. No.: US 2010/0238718 A1
(43) Pub. Date: Sep. 23, 2010

(54) SEMICONDUCTOR MEMORY DEVICE

(75) Inventor: Yoshiaki ASAO, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/727,076

(22) Filed: Mar. 18, 2010

(30) Foreign Application Priority Data
Mar. 23, 2009 (JP) 2009-070579

(51) Int. Cl. G11C 11/00; H01L 29/78

(52) U.S. Cl. 365/158; 257/295; 257/E29.255

(57) ABSTRACT

A semiconductor memory device includes a semiconductor substrate including an active area, a first select transistor in the active area, a first interconnection layer above the semiconductor substrate configured to run in a first direction, a first magnetoresistive element above the first interconnection layer including a fixed layer having a fixed magnetization direction, a nonmagnetic layer on the fixed layer, and a recording layer on the nonmagnetic layer having a variable magnetization direction, the fixed layer being electrically connected to the first interconnection layer, the recording layer being electrically connected to a first diffusion region of the first select transistor, and a second interconnection layer configured to run in the first direction and electrically connected to a second diffusion region of the first select transistor.

### CROSS-REFERENCE TO RELATED APPLICATIONS

This application is based upon and claims the benefit of priority from prior Japanese Patent Application No. 2009-070579, filed Mar. 23, 2009, the entire contents of which are incorporated herein by reference.

### BACKGROUND OF THE INVENTION

1. Field of the Invention

The present invention relates to a semiconductor memory device, e.g., a semiconductor memory device including a memory element using the tunneling magnetoresistive (TMR) effect.

2. Description of the Related Art

Recently, a semiconductor memory using a variable-resistance element as a memory element, e.g., a magnetic random access memory (MRAM) is attracting attention and being developed. The MRAM performs a memory operation by storing binary 1 or 0 in a memory cell by using the TMR effect. Since the MRAM has combined features of non-volatility, high speed operation, high integration and high reliability, it is expected as a universal memory capable of replacing a dynamic random access memory (DRAM).

The MRAM generally uses a magnetic tunnel junction (MTJ) element having a multilayered structure including a first ferromagnetic layer, tunnel barrier layer, and second ferromagnetic layer. The MTJ element stores data (binary 1 or 0) in accordance with the change in relative angle between the magnetization directions in the first and second ferromagnetic layers. Also, when using a method called spin transfer by which a spin-polarized current controls magnetization, the current density is increased by reducing the cell size of the MRAM. This makes it possible to readily reverse the magnetization of a magnetic material, and fabricate a high-density, low-power-consumption MRAM.

In the MTJ element, the magnitude of a write current for spin reversal when the magnetization arrangements in the first and second ferromagnetic layers are changed from a parallel state to an antiparallel state largely differs from that when the magnetization directions are changed from the antiparallel state to the parallel state. Accordingly, when supplying a write current to the MTJ element by using a select transistor, for example, no desired write current can be supplied to the MTJ element if the current driving force of the select transistor is low. This poses the problem that no desired data can be recorded in the MTJ element.

As a related technique of this kind, an MRAM that can be micropatterned and highly integrated by simplifying the structure and fabrication process by reducing the number of layers of a multilayered interconnection structure is disclosed (USP Pat. Appln. Publication No. US2002/0141231).

### BRIEF SUMMARY OF THE INVENTION

According to an aspect of the present invention, there is provided a semiconductor memory device comprising:
a semiconductor substrate comprising an active area;
a first select transistor in the active area;
a first interconnection layer above the semiconductor substrate configured to run in a first direction;
a first magnetoresistive element above the first interconnection layer comprising a fixed layer having a fixed magnetization direction, a nonmagnetic layer on the fixed layer, and a recording layer on the nonmagnetic layer having a variable magnetization direction, the fixed layer being electrically connected to the first interconnection layer, the recording layer being electrically connected to a first diffusion region of the first select transistor; and
a second interconnection layer configured to run in the first direction and electrically connected to a second diffusion region of the first select transistor.

### BRIEF DESCRIPTION OF THE SEVERAL VIEWS OF THE DRAWING

FIG. 1 is a view showing the layout of an MRAM according to the first embodiment of the present invention;

FIG. 2 is a sectional view of the MRAM taken along line A-A′ in FIG. 1;

FIG. 3 is a sectional view of the MRAM taken along line B-B′ in FIG. 1;

FIG. 4 is a sectional view of the MRAM taken along line C-C′ in FIG. 1;

FIG. 5 is a sectional view showing the arrangement of an MTJ element 22;

FIG. 6 is an equivalent circuit diagram of the MRAM;

FIGS. 7A and 7B are graphs showing the IV curves of a select transistor 13;

FIG. 8 is a sectional view showing another arrangement of the MTJ element 22;

FIG. 9 is a view showing the layout of an MRAM according to the second embodiment of the present invention;

FIG. 10 is a sectional view of the MRAM taken along line A-A′ in FIG. 9; and

FIG. 11 is a sectional view of the MRAM taken along line C-C′ in FIG. 9.

### DETAILED DESCRIPTION OF THE INVENTION

The embodiments of the present invention will be described hereinafter with reference to the accompanying drawings. In the description which follows, the same or functionally equivalent elements are denoted by the same reference numerals, to thereby simplify the description.

### First Embodiment

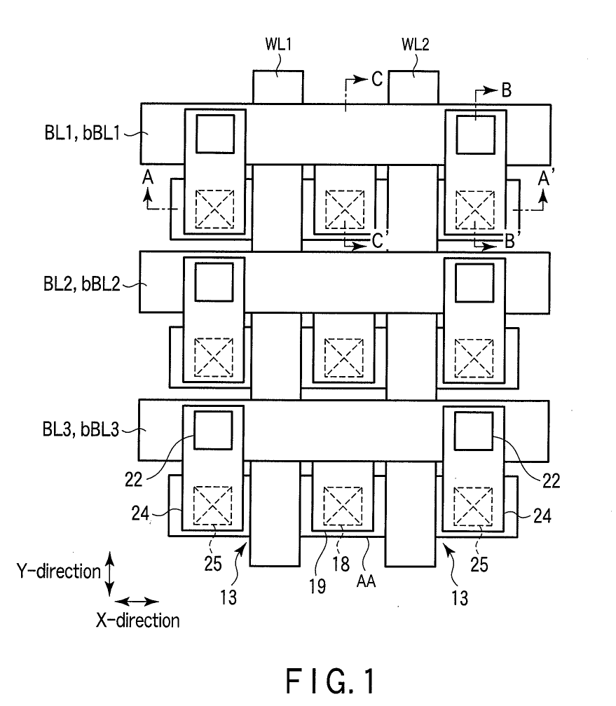

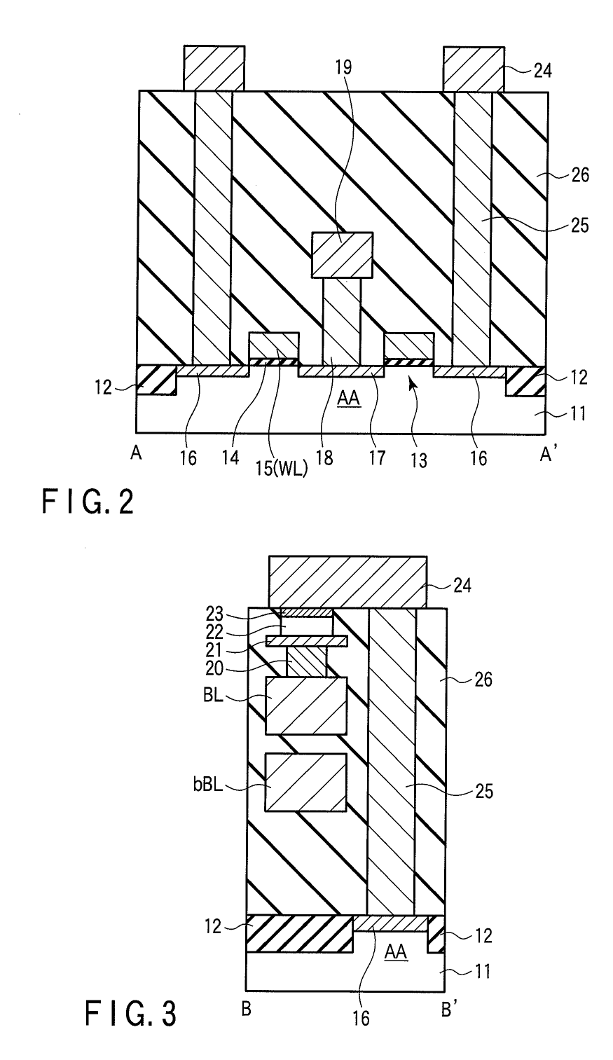

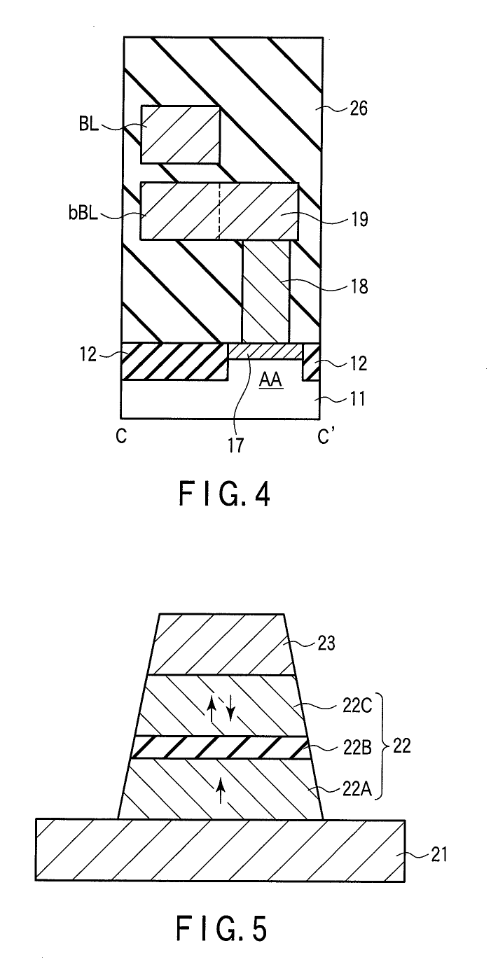

FIG. 1 is a view showing the layout of a nonvolatile semiconductor memory device (MRAM) according to the first embodiment of the present invention. FIG. 2 is a sectional view of the MRAM taken along line A-A′ in FIG. 1. FIG. 3 is a sectional view of the MRAM taken along line B-B′ in FIG. 1. FIG. 4 is a sectional view of the MRAM taken along line C-C′ in FIG. 1.

A p-type semiconductor substrate 11 includes an element isolation insulating layer 12 in the surface region. A region where no element isolation insulating layer 12 is formed is an active area (element region) AA in which an element is to be formed. A plurality of active areas AA are formed in the semiconductor substrate 11. The element isolation insulating layer 12 is formed by, e.g., shallow trench isolation (STI). The STI 12 is made of, e.g., silicon oxide (SiO₂).

Each active area AA is, e.g., a rectangle whose longitudinal direction is the X-direction. A plurality of active areas AA are arranged at equal intervals in the Y-direction (i.e., a direction perpendicular to the X-direction). Also, although not shown in FIG. 1, a plurality of units each including a plurality of active areas AA arranged in the Y-direction are arranged at equal intervals in the X-direction.

Two word lines WL run across each active area AA, and two select transistors 13 are formed at the intersections of the active area AA and two word lines WL. Each select transistor 13 is, e.g., an n-channel metal oxide semiconductor field-effect transistor (MOSFET).

That is, first and second diffusion regions (source/drain regions) 16 and 17 are formed apart from each other in the active area AA. The first and second source/drain regions 16 and 17 are each made of an n⁺-type diffusion region formed by heavily doping an n-type impurity (e.g., phosphorus [P] or arsenic [As]) in the semiconductor substrate 11. On the active region AA between the source/drain regions 16 and 17, a gate electrode 15 extending in the Y-direction is formed on a gate insulating film 14. The gate electrode 15 functions as the word line WL. A first select transistor 13 is thus fabricated. A second select transistor 13 formed in the same active area AA as that of the first select transistor 13 is connected in series with the first select transistor 13 so as to share the source/drain region 17.

A contact plug 18 is formed on the source/drain region 17 shared by the two select transistors 13. An lead interconnection 19 running in the Y-direction is formed on the contact plug 18. The lead interconnection 19 is electrically connected to a second bit line bBL running in the X-direction. In other words, the second bit line bBL running in the X-direction has a projection formed on the same level as that of the second bit line bBL and projecting in the Y-direction. This projection is the lead interconnection 19. The second bit line bBL is electrically connected to the source/drain region 17 via the projection (lead interconnection 19). The lead interconnection 19 has a length reaching the portion above the source/drain region 17 from the side surface of the second bit line bBL.

A first bit line BL running in the X-direction is formed above the second bit line bBL with an insulating layer being formed between them. In the layout shown in FIG. 1, the first bit line BL and second bit line bBL overlap each other.

A contact plug 20 is formed on the first bit line BL. A lower electrode 21 is formed on the contact plug 20. An MTJ element 22 is formed on the lower electrode 21. The planar shape of the MTJ element 22 is not particularly limited, and can be a circle, an ellipse, a square, or any other polygon. The planar shape can also be a polygon having rounded corners, or a polygon having chipped corners. Note that as shown in FIG. 1, a plurality of MTJ elements 22 are arranged above the first bit line BL at equal intervals along the X-direction.

An upper electrode 23 is formed on the MTJ element 22. A lead interconnection 24 running in the Y-direction is formed on the upper electrode 23. The lead interconnection 24 has a length reaching the portion above the source/drain region 16 from the end of the MTJ element 22, and has, e.g., a rectangular planar shape. A contact plug 25 electrically connects the lead interconnection 24 and source/drain region 16. A portion between the semiconductor substrate 11 and the lead interconnection 24 is filled with an interlayer insulating layer 26. The interlayer insulating layer 26 is made of, e.g., silicon oxide (SiO₂).

The arrangement of the MTJ element 22 will be explained below. FIG. 5 is a sectional view showing the arrangement of the MTJ element 22.

The MTJ element 22 has a multilayered structure formed by sequentially stacking the lower electrode 21, a fixed layer (also called a reference layer) 22A, an interlayer (nonmagnetic layer) 22B, a recording layer (also called a free layer) 22C, and the upper electrode 23. That is, the recording layer 22C is formed on the upper side of the interlayer 22B, and the fixed layer 22A is formed on the lower side of the interlayer 22B. The lower electrode 21 and upper electrode 23 are each made of a conductor.

In the recording layer 22C, the magnetization (or spin) direction is variable (reverses). In the fixed layer 22A, the magnetization direction is invariable (fixed). “The magnetization direction in the fixed layer 22A is invariable” means that the magnetization direction in the fixed layer 22A remains unchanged even when a reversing current used to reverse the magnetization direction in the recording layer 22C is supplied to the fixed layer 22A. In the MTJ element 22, therefore, a magnetic layer having a large reversing current is used as the fixed layer 22A, and a magnetic layer having a reversing current smaller than that of the fixed layer 22A is used as the recording layer 22C. This makes it possible to implement the MTJ element 22 including the recording layer 22C having a variable magnetization direction and the fixed layer 22A having an invariable magnetization direction. When causing magnetization reversal by spin-polarized electrons, the reversing current is proportional to the attenuation constant, anisotropic magnetic field, and volume. Accordingly, a difference can be produced between the reversing currents of the recording layer 22C and fixed layer 22A by appropriately adjusting these factors. Also, as a method of fixing the magnetization of the fixed layer 22A, an antiferromagnetic layer (not shown) is formed adjacent to the fixed layer 22A. The magnetization direction in the fixed layer 22A can be fixed by exchange coupling between the fixed layer 22A and the antiferromagnetic layer.

The direction of easy magnetization in the recording layer 22C and fixed layer 22A can be perpendicular to the film surface (or the stacked surfaces) (to be referred to as perpendicular magnetization hereinafter), or parallel to the film surface (to be referred to as in-plane magnetization hereinafter). A perpendicular magnetization magnetic layer has magnetic anisotropy perpendicular to the film surface. An in-plane magnetization magnetic layer has magnetic anisotropy in the direction of plane. When using a perpendicular magnetization MTJ element, it is unnecessary to control the element shape in order to decide the magnetization direction, unlike an in-plane magnetization MTJ element. This is advantageous for micropatterning. In addition, the effect of reducing the reversing current can be obtained by micropatterning the MTJ element 22.

The recording layer 22C and fixed layer 22A are made of a magnetic material having a high coercive force. More specifically, the recording layer 22C and fixed layer 22A preferably have a high magnetic anisotropic energy density of 1×10⁶ erg/cc or more. The interlayer 22B is made of a nonmagnetic material. More specifically, it is possible to use, e.g., an insulator, semiconductor, or metal. The interlayer 22B is called a tunnel barrier layer when using an insulator or semiconductor, and called a spacer layer when using a metal.

Note that each of the fixed layer 22A and recording layer 22C is not limited to a single layer as shown in FIG. 5, and may also have a multilayered structure including a plurality of magnetic layers. Note also that each of the fixed layer 22A and recording layer 22C can have an antiferromagnetically coupled structure which includes three layers, i.e., a first magnetic layer/nonmagnetic layer/second magnetic layer and in which the first and second magnetic layers magnetically couple with each other (by exchange coupling) such that their magnetization directions are antiparallel, or a ferromagnetically coupled structure in which the first and second magnetic layers magnetically couple with each other such that their magnetization directions are parallel.

Data is written in the MTJ element 22 by the spin transfer method by which a write current is supplied to the MTJ element 22. The MTJ element 22 is set in a low-resistance state or high-resistance state by changing the direction of the write current in accordance with data.

In the parallel state (low-resistance state) in which the magnetization directions in the fixed layer 22A and recording layer 22C are parallel, the resistance of the MTJ element 22 is minimum. This state is defined as binary 0. On the other hand, in the antiparallel state (high-resistance state) in which the magnetization directions in the fixed layer 22A and recording layer 22C are antiparallel, the resistance of the MTJ element 22 is maximum. This state is defined as binary 1.

Data read is performed by supplying a read current to the MTJ element in one direction. Letting R0 be the resistance in the parallel state and R1 be that in the antiparallel state, a value defined by (R1-R0)/R0 is called the magnetoresistive ratio (MR ratio). Although the magnetoresistive ratio changes in accordance with the materials and process conditions of the MTJ element 22, the magnetoresistive ratio can vary from about a few tens percent to about a few hundred percent. Data stored in the MTJ element 22 is read by sensing the magnitude of a read current caused by this MR ratio. A read current to be supplied to the MTJ element 22 in a read operation is set to be much smaller than a current that reverses the magnetization of the recording layer 22C by spin transfer.

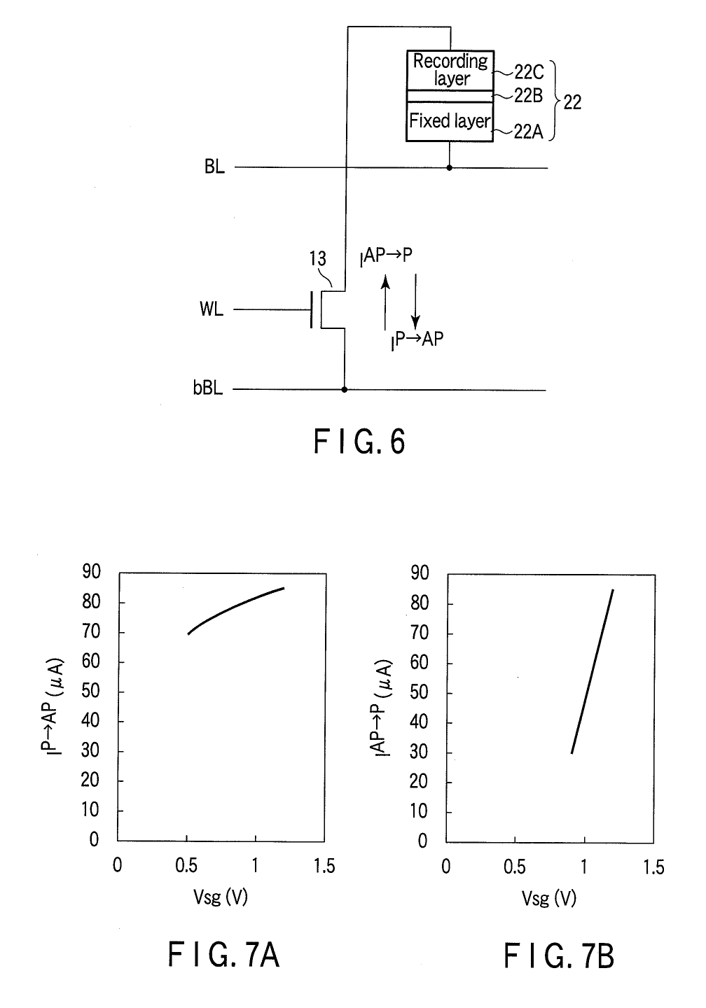

FIG. 6 is an equivalent circuit diagram of the MRAM of this embodiment. The first bit line BL is electrically connected to the fixed layer 22A of the MTJ element 22. The recording layer 22C of the MTJ element 22 is electrically connected to one end of the current path of the select transistor 13. The other end of the current path of the select transistor 13 is electrically connected to the second bit line bBL.

In the following description, “I^{P→AP}” represents a write current that spin-reverses the magnetization directions (spin directions) in the fixed layer 22A and recording layer 22C from the parallel state to the antiparallel state, and “I^{AP→P}” represents a write current that spin-reverses these magnetization directions from the antiparallel state to the parallel state. When supplying the write current I^{P→AP} to the MTJ element 22, the select transistor 13 is driven while the first bit line BL is biased to a potential higher than that of the second bit line bBL. On the other hand, when supplying the write current I^{AP→P} to the MTJ element 22, the select transistor 13 is driven while the second bit line bBL is biased to a potential higher than that of the first bit line BL.

Generally, the write current I^{P→AP} is greater than the write current I^{AP→P}.

I^{P→}>I^{AP→P}

The current driving force of the select transistor 13 defines the write current to be supplied to the MTJ element 22. The current driving force of the select transistor 13 when supplying the write current I^{P→AP} differs from that when supplying the write current I^{AP→P}; the current driving force when supplying the write current I^{P→AP} is greater than that when supplying the write current I^{AP→P}. This is so because the MTJ element 22 functions as a resistance element. That is, when supplying the write current I^{P→AP}, the second bit line bBL is at low potential (e.g., 0 V), so the source of the select transistor 13 is at 0 V. This increases the current driving force of the select transistor 13.

On the other hand, when supplying the write current I^{AP→P}, the first bit line BL is at 0 V, so the source potential of the select transistor 13 floats from 0 V by the IR drop of the MTJ element 22, and a source-to-gate voltage Vsg of the select transistor 13 lowers. Accordingly, the back bias effect decreases the current driving force of the select transistor 13.

FIG. 7A shows the current-voltage characteristic (IV curve) of the select transistor 13 when supplying the write current I^{P→AP}. FIG. 7B shows the IV curve of the select transistor 13 when supplying the write current I^{AP→P}. The comparison of FIGS. 7A and 7B reveals that when a high potential to be applied to any bit line during data write is 1 V, the write current I^{P→AP} is greater than the write current I^{AP→P}. That is, the current driving force of the select transistor 13 when supplying the write current I^{P→AP} is higher than that when supplying the write current I^{AP→P}.

In this embodiment as shown in FIG. 6, the fixed layer 22A is electrically connected to the first bit line BL and the recording layer 22C is electrically connected to the select transistor 13, so as to increase the current driving force of the select transistor 13 when a large current is necessary during data write, i.e., when supplying the write current I^{P→AP}.

When the recording layer 22C is formed above the fixed layer 22A as in this embodiment, it is possible to improve the magnetic characteristic of the MTJ element 22, and further reduce the reversing current. To fabricate the MTJ element 22 shown in FIG. 5, the first magnetic layer 22A, nonmagnetic layer 22B, and second magnetic layer 22C are sequentially deposited on an underlayer (not shown) for controlling the crystal orientation, and a hard mask is formed on the second magnetic layer 22C by using, e.g., lithography and reactive ion etching (RIE). This hard mask is used as a mask to process the multilayered film by, e.g., ion milling.

In this structure, the formed MTJ element 22 has a tapered shape that widens downward. That is, the volume of the first magnetic layer 22A is greater than that of the second magnetic layer 22C. If the first magnetic layer 22A having a large volume is used as the recording layer, the reversing current increases, and the magnetization reversing operation becomes unstable because the recording layer has a multi-domain structure. In this embodiment, the second magnetic layer 22C having a small volume is used as the recording layer. Since the recording layer has a single-domain structure, the magnetization reversing operation stabilizes, and the reversing current can further be reduced.

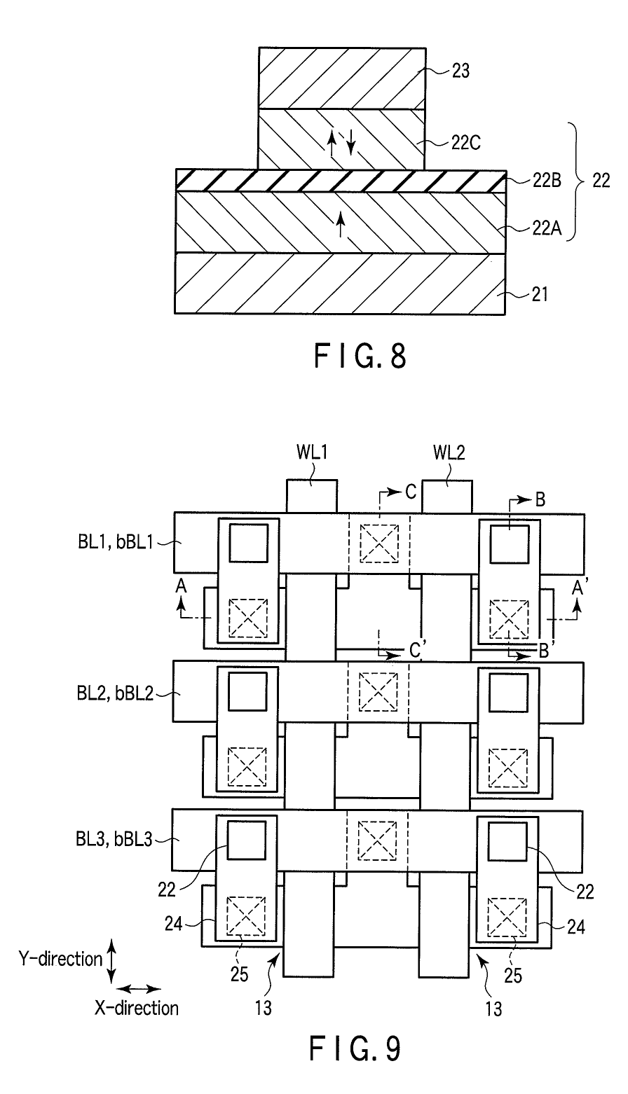

Also, the volume of the recording layer 22C defines the magnitude of the reversing current, and the shape and size of the fixed layer 22A are not limited as long as the magnetization direction is fixed. That is, the fixed layer 22A need not be processed into the same shape as that of the recording layer 22C. FIG. 8 is a sectional view of the MTJ element 22 when the recording layer 22C alone is processed by using the upper electrode 23 as a hard mask. When fabricating the MTJ element 22 like this, the recording layer 22C alone needs to be accurately processed. This makes it possible to simplify the fabrication process, and reduce the cost. In addition, as described previously, when an underlayer for controlling the crystal orientation is formed under the fixed layer 22A, or when an antiferromagnetic layer is formed under the fixed layer 22A, it is unnecessary to process the underlayer or antiferromagnetic layer. Accordingly, the etching step can further be simplified.

In the first embodiment as described in detail above, the recording layer 22C is formed on the nonmagnetic layer 22B and the fixed layer 22A is formed under the nonmagnetic layer 22B in order to improve the magnetic characteristic of the MTJ element 22. Furthermore, the fixed layer 22A is electrically connected to the first bit line BL, and the recording layer 22C is electrically connected to the second bit line bBL via the lead interconnection 24 and select transistor 13.

In the first embodiment, therefore, the current driving force of the select transistor 13 can be increased when supplying the write current I^{P→AP} to the MTJ element 22 by biasing the first bit line BL to a potential higher than that of the second bit line bBL. Accordingly, even when a current greater than the write current I^{AP→P} is necessary as the write current I^{P→AP}, a write current having the desired magnitude can be supplied to the MTJ element 22. Consequently, it is possible to correctly perform a write operation to the MTJ element 22, and prevent a write error to the MTJ element 22.

Also, the recording layer 22C can accurately be processed by forming the recording layer 22C on the nonmagnetic layer 22B and the fixed layer 22A under the nonmagnetic layer 22B. In addition, the volume of the recording layer 22C can be decreased even when the MTJ element 22 is tapered. This makes it possible to improve the magnetic characteristic of the MTJ element 22, and reduce the reversing current.

### Second Embodiment

The second embodiment is another configuration example of the first embodiment. In the second embodiment, an active area AA is formed into a T-shape, and a straight bit line bBL is electrically connected to the active area AA by using a contact plug.

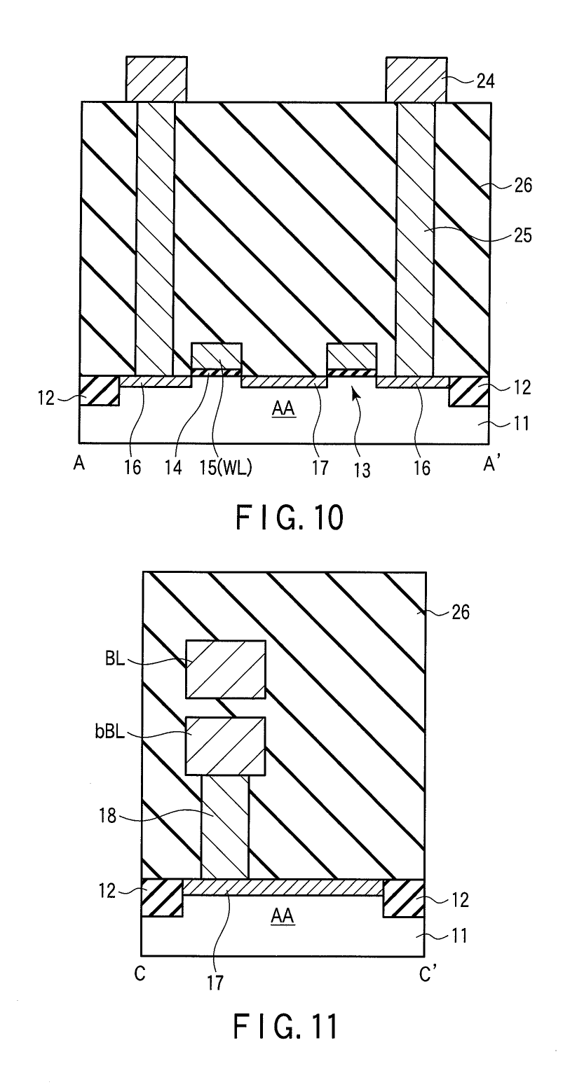

FIG. 9 is a view showing the layout of an MRAM according to the second embodiment of the present invention. FIG. 10 is a sectional view of the MRAM taken along line A-A′ in FIG. 9. FIG. 11 is a sectional view of the MRAM taken along line C-C′ in FIG. 9. A sectional view of the MRAM taken along line B-B′ in FIG. 9 is the same as in FIG. 3.

Each active area AA has a T-shape. More specifically, the active area AA includes an extending portion extending in the X-direction, and a projection projecting in the Y-direction from the center of the extending portion. A plurality of active areas AA are arranged at equal intervals along the Y-direction. Although not shown in FIG. 9, a plurality of units each including a plurality of active areas AA arranged in the Y-direction are arranged at equal intervals in the X-direction.

Two word lines WL run across the active area AA so as to sandwich the projection. Also, two select transistors 13 having the two word lines WL as gate electrodes 15 are formed in the active area AA.

That is, first and second diffusion regions (source/drain regions) 16 and 17 are formed apart from each other in the active area AA. On the active area AA between the source/drain regions 16 and 17, the gate electrode 15 extending in the Y-direction is formed on a gate insulating film 14. A first select transistor 13 is thus formed. A second select transistor 13 formed in the same active area AA as that of the first select transistor 13 is connected in series with the first select transistor 13 so as to share the source/drain region 17.

A contact plug 18 is formed on the end portion (i.e., the projection) of the source/drain region 17 shared by the two select transistors 13. The straight bit line bBL is formed on the contact plug 18. In the second embodiment, therefore, the bit line bBL has no lead interconnection 19, and the contact plug 18 electrically connects the straight bit line bBL and source/drain region 17, unlike the first embodiment.

The arrangements of an MTJ element 22 and lead interconnection 24 are the same as those of the first embodiment. The same effects as those of the first embodiment can be obtained even when the MRAM is fabricated as described above.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a semiconductor substrate comprising an active area, the active area comprising a first select transistor;
a first interconnection layer on the semiconductor substrate configured to run in a first direction;
a first magnetoresistive element on the first interconnection layer comprising:
a fixed layer comprising a fixed magnetization direction,
a nonmagnetic layer, and
a recording layer comprising a variable magnetization direction;
wherein the fixed layer is electrically connected to the first interconnection layer and the recording layer is electrically connected to a first diffusion region of the first select transistor; and
a second interconnection layer configured to run in the first direction and electrically connected to a second diffusion region of the first select transistor.

2. The device of claim 1, wherein the first magnetoresistive element is configured to be set in a high-resistance state by a first write current and a low-resistive state by a second write current, the first write current being greater than the second write current.

3. The device of claim 1, wherein
a voltage of the second interconnection layer is lower than a voltage of the first interconnection layer when setting the first magnetoresistive element in a high-resistance state, and
a voltage of the first interconnection layer is lower than a voltage of the second interconnection layer when setting the first magnetoresistive element in a low-resistance state.

4. The device of claim 1, wherein the first diffusion region further comprises a contact plug and further comprising a first lead interconnection configured to electrically connect the recording layer and the contact plug.

5. The device of claim 1, wherein the second interconnection layer is below the first interconnection layer.

6. The device of claim 1, further comprising a first contact plug configured to electrically connect the fixed layer and the first interconnection layer.

7. The device of claim 1, wherein the second diffusion region further comprises a contact plug, the contact plug electrically connected to the second interconnection layer.

8. The device of claim 6, wherein the second diffusion region further comprises a second contact plug configured to be electrically connected to the second interconnection layer;
the device further comprising a second lead interconnection which electrically connects the second interconnection layer and the first contact plug.

9. The device of claim 1, wherein:
the active area further comprises a second select transistor electrically connected to the first select transistor, and
the first select transistor and the second select transistor are configured to share the second diffusion region; and
further comprising a second magnetoresistive element electrically connected to the second select transistor.

10. The device of claim 9, wherein the active region is substantially rectangular.

11. The device of claim 9, wherein the active area further comprises:
a first member extending in the first direction and
a second member projecting from a substantially central area of the first member in a second direction substantially perpendicular to the first direction.

12. The device of claim 11, wherein the second member further comprises the second diffusion region.

13. The device of claim 11, wherein:
the first select transistor comprises a first gate electrode comprising a gate insulating film, and
the second select transistor comprises a second gate electrode comprising a gate insulting film.

14. The device of claim 13, wherein the second diffusion region is substantially between the first gate electrode and the second gate electrode.

15. The device of claim 1, wherein a volume of the recording layer is smaller than a volume of the fixed layer.

16. The device of claim 1, wherein the first magnetoresistive element is configured to have a substantially tapered vertical cross section, wherein a lower portion of the magnetoresistive element is wider than a higher portion of the magentoresistive element.
